(19) United States
(12) Patent Application Publication
(10) Pub. No.: US 2005/0104600 A1
(43) Pub. Date: May 19, 2005

(54) Vehicle for inspecting a pipe

(75) Inventor: Dave James Cotton, Hants (GB)

Correspondence Address: BAKER & HOSTETLER LLP;Washington Square, Suite 1100, 1050 Connecticut Avenue, N.W., WASHINGTON, DC, 20036, US

(73) Assignee: Radiodetection Limited

(21) Appl. No.: 10/714,860

(22) Filed: Nov. 18, 2003

(51) Int. Cl. G01R 31/08

(52) U.S. Cl. 324/519

(57) ABSTRACT

The present invention provides a vehicle for inspecting a pipe including a chassis; propulsion means for driving the chassis along the pipe; and sensor means which when located adjacent an interior surface of the pipe provide a signal indicative of the presence of lateral openings in the pipe; the sensor means comprising a capacitive sensor.

### FIELD OF THE INVENTION

The present invention relates to a vehicle for inspecting and optionally restoring a pipe.

### BACKGROUND OF THE INVENTION

Pipeline inspection and restoration vehicles are known. For instance, a Canadian company produces a pipeline inspection vehicle called the “Microtrack Crawler.” This has three drive units, each with a caterpillar track, in a tripod formation. The vehicle is remotely controlled and transports a variety of testing and inspection equipment such as a rotating and tilting color camera.

U.S. Pat. No. 6,031,371 describes a pipeline vehicle which has a train of modules interlinked by suspension units to allow serpentine movement through pipe bends. The vehicle has its own internal power supply and drive mechanism. The vehicle incorporates a detector for determining the presence of a lateral pipe using a magnetic field. The vehicle is provided with a mechanism which allows the vehicle to be wedged in the pipeline while drilling and welding operations are carried out. The vehicle does not carry any video inspection equipment. It operates largely independently from surface control, although in one embodiment a radio link is provided so that the vehicle can communicate with a surface control station.

Furthermore, prior art vehicles have operated e.g. cutting equipment either electrically using an onboard power supply or a power supply from the surface, or hydraulically using pressurized hydraulic fluid supplied by a line connected to the surface. It is difficult to apply sufficient pressure on a cutting tool using electrical power alone. On the other hand, it is generally not practical to operate cutting equipment using hydraulic power supplied from the surface because the vehicle has to drag with it heavy hydraulic pipes, which limits its maneuverability and its range.

Additionally, pipeline vehicles are often used when an existing cracked pipe is made watertight by use of a liner. After initial installation of the liner a pipeline vehicle is often used to cut apertures in the liner to allow communication of the relined pipe with the existing branch pipes which branch off the relined pipe. The prior art vehicles have concerned themselves with the sensing of the position of lateral branch pipes off of metal pipes and hence have used magnetic sensors ideal for the purpose. When metal pipes are not present then it has been necessary to use metal inserts in the branch pipes in order to permit working of the magnetic sensors.

### SUMMARY OF THE INVENTION

In a first embodiment, the present invention provides a vehicle for inspecting a pipe including a chassis; propulsion means for driving the chassis along the pipe; and sensor means which when located adjacent an interior surface of the pipe provide a signal indicative of the presence of lateral openings in the pipe; the sensor means comprising a capacitive sensor.

The vehicle may be adapted for restoring a pipe, by providing additionally cutting means mounted on the chassis includes a cutting tool capable of cutting through a liner lining the pipe; and actuator means for moving the cutting means relative to the chassis.

Preferably, there are camera means to provide an image of the interior of the pipe.

Where cutting means are provided, the propulsion means, the cutting means and the actuator means are all electrically controllable by a human operator using electrical control means; and preferably the actuator means comprises a hydraulic ram powered by hydraulic fluid pressurised by an electrically operated pump mounted on the chassis of the vehicle and controllable by the control means.

The preferred embodiment of the present invention provides an onboard generator of hydraulic pressure, powered electrically. Therefore, hydraulic pressure can be applied to the cutting equipment without a need for the vehicle to drag behind it a hydraulic pipeline. Only an electrical supply is needed.

Furthermore, the preferred embodiment of the present invention uses a capacitive sensor which can detect the presence of lateral branch pipes of any material, e.g. concrete, plastic.

In a further embodiment, the present invention provides a vehicle for inspecting a pipe, comprising a chassis with an electric motor drive for propelling it along the interior of the pipe; the vehicle having a capacitive sensor for movement adjacent an interior surface of the pipe to provide a signal indicative of the presence of the lateral openings in the file.

There has thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

A preferred embodiment of the present invention will now be described with reference to the accompanying drawings in which:

FIG. 1 is a perspective view of a preferred embodiment of a vehicle for inspecting and repairing a vehicle.

FIG. 2 is a view of the vehicle of FIG. 1 in a pipeline in a first operating mode.

FIG. 3 is a view of the vehicle of FIG. 1 in a pipeline in a second operating mode.

FIG. 4 is a cross-section through a drive unit of the vehicle shown in FIGS. 1 to 3.

### DETAILED DESCRIPTION

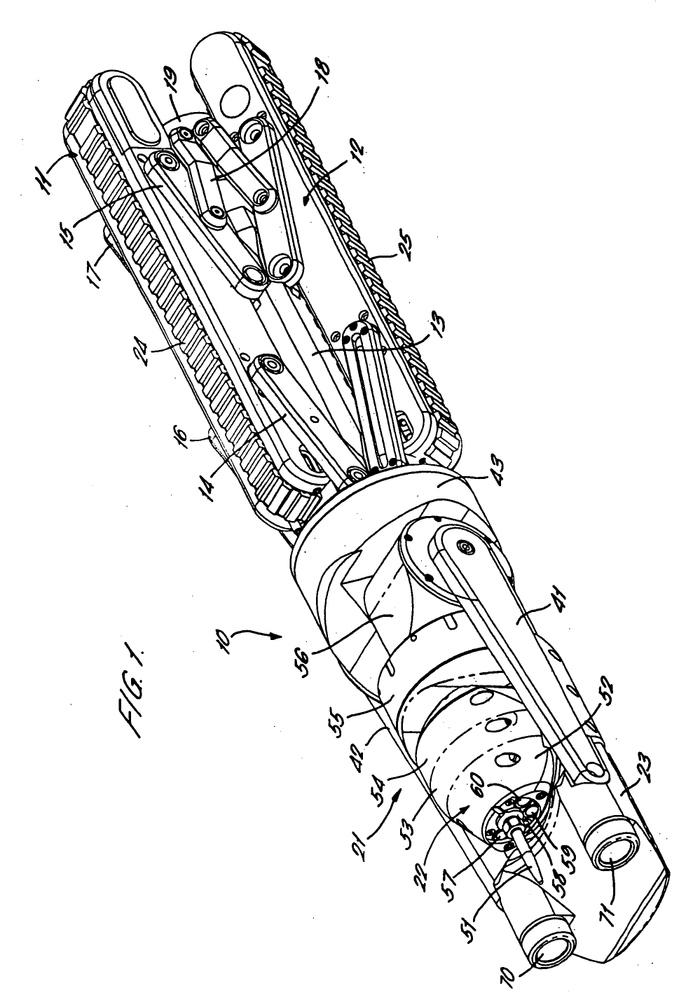

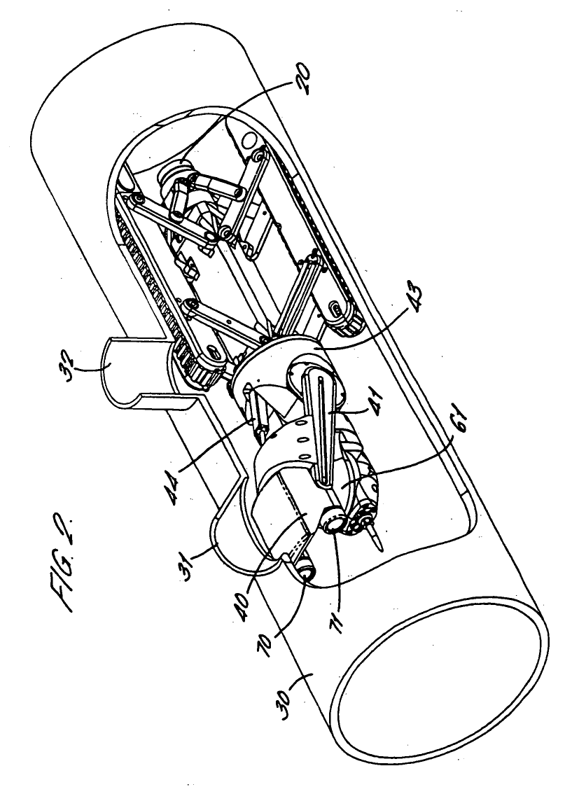

Turning first to FIG. 1 there can be seen in the figure a vehicle 10 of a preferred embodiment of the present invention. The vehicle comprises three drive units (drive units 11, 12 can be seen in the figures—a third identical drive unit, equi-angularly disposed around the longitudinal axis, is not visible). Each drive unit is hingedly attached to a vehicle body 13 by four arms, e.g. 14, 15, 16, 17, each pivotally connected at one end to a drive unit and pivotally connected at the other end to the vehicle body 13. Each of the rearward two arms of each set of four has pivotally connected thereto at a midpoint a control arm, e.g. 18. Each control arm (e.g. 18) is pivotally connected at one end to a hub 19 which is slidable on a core 20 (see FIG. 2) towards and away from the vehicle body 13. By virtue of the arrangement of hinged arms, a sliding of the hub 19 towards the vehicle body 13 pushes the three drive units, e.g. 11, 12, radially outward from the vehicle body 13 and sliding of the hub 19 away from the vehicle body 13 brings previously extended drive units, e.g. 11, 12, radially inwards toward the vehicle body 13.

Mounted at the front of the vehicle body 13 is a pipeline inspection and cutting head 21. The head 21 is rotatably mounted on the body 13 and a motor is provided to rotate the head 21 about its longitudinal axis. The head 21 comprises a cutting unit 22 and a combined camera and detection unit 23.

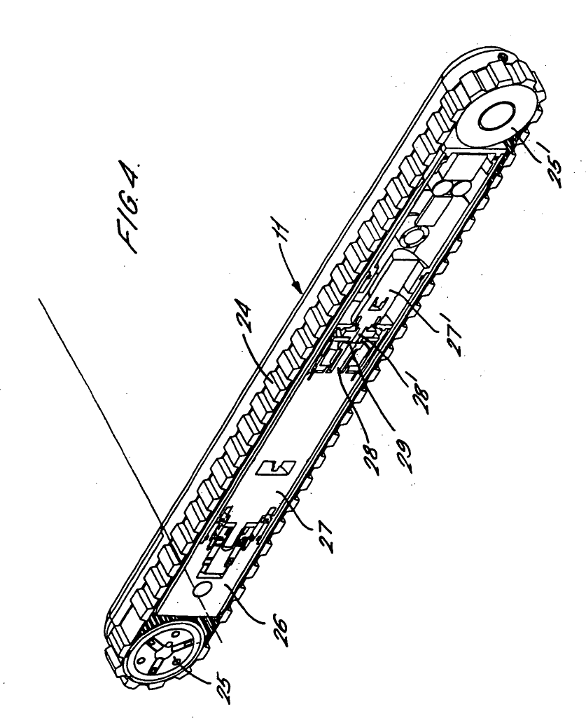

Each drive unit (e.g. 11, 12) comprises a caterpillar track e.g. 24, 25 which is used to engage and grip an interior surface of a pipeline. One drive unit 11 is shown in detail in FIG. 4. It can be seen that the caterpillar track 24 extends around two sprockets 25,25′rotatably mounted one at each end of the drive unit 11. The sprocket 25 is connected via a gearbox 26 to a first electric motor 27. The drive unit 11 is also provided with a second electric motor 27′, smaller than the first electric motor 27. The spindles 28, 28′ of both electric motors 27,27′ are aligned and a clutch 29 is interposed between the two spindles and can allow the spindles 28,28′ to be locked together to rotate together. The drive unit can operate in two different modes. In a first operating mode the larger electric motor is used to drive the caterpillar track to rotate to drive the vehicle along a pipeline at a speed in a range of speeds suitable for inspection purposes. In this mode the clutch 29 decouples the spindles 28 and 28′. In a second operating mode the larger motor 27 is kept inactive, the clutch 29 is operated to lock the two spindles 28,28′ to move together and the motor 27′ is used to drive the caterpillar track 24, via the spindle 28 of the inactive motor 27 and via the gearbox 26. In the second operating mode the smaller electric motor 27′ is used to drive the vehicle in a lower speed range suitable for the control of the vehicle during a cutting operation.

FIG. 2 shows the vehicle 10 in the first operating mode progressing down a main pipe 30. The pipe 30 has been relined with a liner (not shown for simplicity) and it is now necessary to find laterally extending pipes e.g. 31,32 branching off the main pipe and to cut apertures in the liner to allow communication between the main pipe 30 and the branch pipes 31,32.

When the vehicle 10 is first placed in the pipe 30 e.g. through a manhole then the hub 19 will be in its most spaced apart position from the vehicle body 13 and the three drive units e.g. 11,12 will be retracted close to the body 13. Then, via an electrical control cable (not shown), which in use of the vehicle 10 is dragged behind the vehicle, an onboard electrically powered pump (not shown) will be controlled to supply pressurized hydraulic fluid to a hydraulic ram (not shown) which will pull the hub 20 towards the vehicle body 13 and thus pivot the three drive units, e.g. 11, 12, away from the vehicle body 13 until their caterpillar tracks e.g. 24,25 engage the inner surface of the liner lining the pipe 30. The ram used to pivot the drive units is supplied by hydraulic fluid supplied by an onboard pump rather than hydraulic fluid supplied from an external source. Thus the vehicle 10 does not need to drag behind it a heavy hydraulic fluid supply line.

To locate the branch pipes 31,32 a capacitive sensor 40 is used. The capacitive sensor 40 can detect the presence of lateral branch pipes of any material, e.g. concrete, plastic, metal, branching off a main pipe of any material, e.g. concrete, plastic, metal. The capacitive sensor 40 comprises an arcuate plate mounted at the end of two control arms 41,42 which are pivotally mounted on a hub 43 and which are pivoted relative to the hub 43 by extension and contraction of a hydraulic ram 44 which is also pivotally mounted on the hub 43. The hydraulic ram 44 is powered by hydraulic fluid supplied from the on-board pump described above. The hub 43 is rotatable about its own axis, which is approximately coincident with the axis of the pipe 30.

The vehicle 10 in its inspection mode is advanced down the pipe 10 using the larger electric motors, e.g. 27, of the drive units. In the inspection mode the capacitive sensor 40 is pivoted into abutment with the liner which lines the inner wall of the pipe 30. The hub 43 is rotated by an electric motor as the vehicle 10 advances so that the capacitive sensor is rotated around the entire inner circumference of the pipe 30.

Two camera units 70,71 are mounted along with the capacitive sensor 40 at the ends of the pivotal control arms 40,41. They face forward and typically comprise lights ,e.g. LEDs, to illuminate the interior of the pipe 30. The video signals from the cameras 70,71 are relayed to via an electrical cable dragged behind the vehicle 10 to a video display unit used by an operator of the vehicle 10.

A leakage current will pass through the capacitive sensor 40 to earth via the pipe 30, with the plate of the sensor and the adjacent pipe 30 together acting as two plates of a capacitor. Variations in the level of the leakage current are monitored, e.g by a graphic display of the video display unit used by the operator, and are used to detect the presence of lateral side branch pipes.

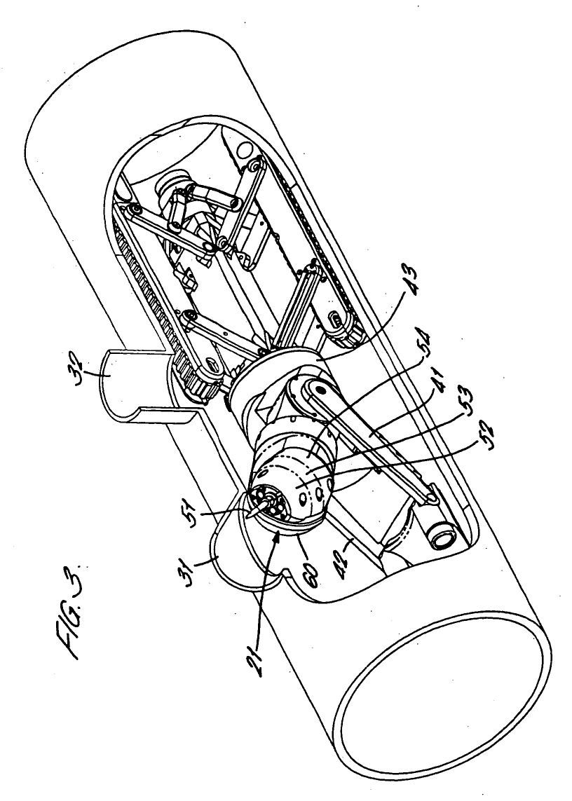

Once a branch pipe has been detected then the vehicle 10 will be stopped. The plate of the capacitive sensor 40 is rotated 180 degrees to engage a surface of the liner of the pipe 30 opposite the detected lateral pipe. This is shown in FIG. 3. The plate of the sensor 40 then serves to steady the vehicle 10 by providing a reaction force in opposition to the force on the vehicle 10 arising during drilling of an aperture in the pipe liner immediately opposite the capacitive sensor plate.

In FIG. 3 the cutting and inspection head 21 is clearly shown. A cutting tool 51 extends forward from the cutting and inspection head 21. The cutting and inspection head 50 comprises three segments 52,53 and 54 rotatable relative to one another. The abutting surfaces of the three segments are shaped so that when they are rotated relative to one another the orientation of the cutting tool 51 is varied. The segments 52, 53 and 54 are rotatable under the action of one or more electric motors which are controlled by the operator of the vehicle 10. Alternatively the segments 52,53,54 could be rotated using pressurized hydraulic fluid supplied by the on-board pump mentioned above. The cutting head 50 is rotatably mounted on a hub 55 and can be rotated relative thereto by an electric motor under control of the operator of the vehicle 10. The hub 55 is mounted at the end of an arm 56 which is pivotally mounted on the rotatable hub 43. A hydraulic ram is used to pivot the arm 56 relative to the hub 43. The hydraulic ram is supplied with pressure from the on-board pump mentioned above. The hydraulic ram is able to apply a force on the cutting tool 51 sufficient to facilitate the cutting of a liner. The various interconnections described above enable the drill 51 to be moved in a plurality of different directions during cutting. In particular the rotation of the segments 52,53 and 54 relative to each other render the apparatus a multi-axis apparatus.

During cutting the clutches e.g. 29 in the drive units e.g. 24 are operated to connect together the spindles of the two electric motors e.g. 27,27′. The vehicle 10 is then driven by the smaller electric motor of each pair of electric motors with the larger motor of each pair rendered inoperative. The larger motor is still rotatable with some slight frictional drag. The use of the smaller motors will allow precise control of the position of the vehicle 10 and thus precise control of the position of the cutting tool 51.

The cutting head 50 is provided with an array of cameras and lights 57,58,59,60 which are aligned with the cutting tool 51. During a cutting operation the cameras and lights 57,58,59,60 will be used to provide images to the video display unit use by the operator in order to guide the cutting operation. The cameras and lights 57,58,59,60 are protected by a spinning or rotating blade 61 which serves to deflect debris away from them during the cutting operation.

The motion of the vehicle itself is thus used during a cutting operation to control the position of the cutting tool 51. The speed of the vehicle 10 is changed from a range of transport speeds (typically 0.25 ms⁻¹ to 0.5 ms⁻¹) which are possible when the vehicle is driven by the large electric motors to a range of creep speeds (typically 0.004 ms⁻¹ to 0.008 ms⁻¹) which are possible when the vehicle is driven by the smaller electric motors. For instance the larger motors may be large gear motors operating with a 10:1 ratio between motor speed and spindle speed and the smaller motors may be small gear motors with 18:1 reduction ratio.

In FIG. 3 it is shown that the cutting tool 51 is cutting through a liner to allow communication between a lateral pipe 31 and the main pipe. The vehicle 10 will be brought along the main pipe using the larger motors until the presence of the lateral pipe 31 is detected by the capacitive sensor. The vehicle will then be moved back and forth by the smaller motors until the middle of the lateral aperture can be estimated and then it is stopped. The sensor is rotated 180 degrees and then the cutting tool 51 is forced through the liner with the directly opposite capacitive sensor now acting to provide a reaction surface to counter the forces on the vehicle occasioned during cutting. Then the cutting tool 51 is moved around the periphery of the lateral aperture defined by the mouth of the pipe 31, with the operator using both the motors in the inspection and cutting head 22 and the small motors of the drive units e.g. 11,12 to control the movement of the cutting tool 51 and thus the cutting operation.

Once a suitable aperture has been cut in the pipe liner then the operator will retract the cutting tool 51 and switch the vehicle 10 from its FIG. 3 cutting mode to its FIG. 2 inspection mode and then advance the vehicle at inspection speed down the pipe 30 to find the next lateral branch pipe.

In a variation of the device mentioned above, the camera units 70,71 will be operated as cameras in a stereo camera system to record images which can be played back by two eye piece viewing glasses to give an operator a three dimensional view. The image provided by one camera would be sent to one eye piece and the image provided by the other camera would be sent to the other eye piece. The video signals would be multiplexed and then relayed on to the viewing apparatus via one channel.

Additionally it would be possible to offer a cheaper arrangement by using a first and second array of charge-coupled devices (CCDs) linked in a common camera system rather than two separate cameras 70,71. The common camera system would switch between the two CCD arrays to sample an image from one and then the other.

The use of a stereoscopic arrangement of cameras or CCDs would also be useful for the array of lights and cameras 57,58,59,60.

While the preferred embodiment of the invention has a cutter, this is not essential, and the vehicle's propulsion system and/or its capactive sensor could be used for other purposes, such as pipeline fault detection.

The many features and advantages of the invention are apparent from the detailed specification, and thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and accordingly, all suitable modifications and equivalents may be resorted to, falling within the scope of the invention.

1. A vehicle for inspecting a pipe comprising:
a chassis;
propulsion means for driving the chassis along the pipe; and
sensor means which when located adjacent an interior surface of the pipe provide a signal indicative of the presence of lateral openings in the pipe wherein the sensor means comprises a capacitive sensor.

2. The vehicle as in claim 1, wherein the capacitive sensor comprises a plate for location adjacent to and spaced from an interior surface of the pipe, such that in use the plate and the portion of the pipe adjacent thereto function as a pair of plates in a capacitor.

3. The vehicle as in claim 1, the sensor means comprising means for detecting a trickle current which, in use, passes through the capacitive sensor to the pipe, the trickle current providing the signal which is indicative of the presence of lateral openings in the pipe.

4. The vehicle as in claim 1, comprising cutting means mounted on the chassis comprising a cutting tool capable of cutting through a liner lining the pipe, and actuator means for moving the cutting means relative to the chassis, the propulsion means, the cutting means and the actuator means all being electrically controllable by a human operator using electrical control means.

5. The vehicle as in claim 1, comprising camera means to provide an image of the interior of the pipe.

6. The vehicle as in claim 4, wherein the actuator means is operable to move the sensor means relative to the chassis.

7. The vehicle as in claim 6, wherein the actuator means can engage the sensor means with one part of the interior surface of the pipe while forcing the cutting means to cut an aperture in a directly opposite part of the pipe whereby the engagement of the sensor means with the first part of the pipe provides a force which reacts to forces arising during a cutting operation and thereby stabilises the vehicle during the cutting operation.

8. The vehicle as in claim 4, wherein the actuator means comprises a hydraulic ram powered by hydraulic fluid pressurised by an electrically operated pump mounted on the chassis of the vehicle and controllable by the control means.

9. The vehicle as in claim 8, wherein the pump is connectable to an electrical cable dragged behind the vehicle to receive electrical power therefrom.

10. The vehicle as in claim 9, wherein the propulsion means, the cutting means and the actuator means are all connectable to the electrical cable to receive electrical power and control signals therefrom.

11. The vehicle as in claim 8, wherein the propulsion means comprises a plurality of caterpillar tracked drive units pivotally connected to the chassis which are pivoted relative to the chassis by a/the hydraulic ram powered by hydraulic fluid supplied by the hydraulic pump mounted on the chassis.

12. The vehicle as in claim 8, wherein the actuator means is operable to move the sensor means relative to the chassis and the sensor means is connected to a/the hydraulic ram powered by hydraulic fluid supplied by the hydraulic pump mounted on the chassis.

13. The vehicle as in claim 1, comprising means for rotating the sensor means about the longitudinal axis of the vehicle.

14. A vehicle for inspecting a pipe, comprising a chassis with an electric motor drive for propelling it along the interior of the pipe; the vehicle having a capacitive sensor for movement adjacent an interior surface of the pipe to provide a signal indicative of the presence of the lateral openings in the file.
